(19) United States
(12) Patent Application Publication
(10) Pub. No.: US 2026/0255740 A1
(43) Pub. Date: Aug. 27, 2026

(54) LIGHT EMITTING DEVICE, METHOD OF MANUFACTURING LIGHT EMITTING DEVICE, AND IMAGE DISPLAY APPARATUS

(71) Applicant: SONY SEMICONDUCTOR SOLUTIONS CORPORATION, Kanagawa (JP)

(72) Inventors: Toshiaki HASEGAWA, Kanagawa (JP); Toshihiro MIURA, Kanagawa (JP); Hiroyuki KASHIHARA, Kanagawa (JP)

(73) Assignee: SONY SEMICONDUCTOR SOLUTIONS CORPORATION, Kanagawa (JP)

(21) Appl. No.: 19/162,725

(22) PCT Filed: Feb. 16, 2024
(86) PCT No.: PCT/JP2024/005411

§ 371 Date: Sep. 5, 2025

(30) Foreign Application Priority Data
Mar. 24, 2023 (JP) 2023-048659

(51) Int. Cl. H10H 20/833; H10H 20/01; H10H 20/821; H10H 20/831; H10H 20/841; H10H 20/857

(52) U.S. Cl. CPC H10H 20/833; H10H 20/032; H10H 20/034; H10H 20/0364; H10H 20/821; H10H 20/831; H10H 20/841; H10H 20/857

(57) ABSTRACT

A light emitting device including: a driving substrate; a compound semiconductor layer, the compound semiconductor layer including a first electrical conductivity type layer, an active layer, and a second electrical conductivity type layer that are stacked in this order from a side of the driving substrate, and including a mesa section that includes the first electrical conductivity type layer, the active layer, and a portion of the second electrical conductivity type layer; a first transparent electrode layer on a side of the first electrical conductivity type layer that is closer to the driving substrate, and including an enlarged-width section that is larger in width than the mesa section; and a first light reflection film around the mesa section with a first insulating film therebetween, the first light reflection film forming an inclined surface that is at an acute angle with respect to the first surface.

### TECHNICAL FIELD

The present disclosure relates to a light emitting device, a method of manufacturing the light emitting device, and an image display apparatus including the same.

### BACKGROUND ART

For example, Patent Literature 1 discloses a micro light emitting element having a body including a P-side layer, a light emission layer, and an N-side layer that are stacked in order from a light emitting surface side, in which a side surface of the body is inclined to open in a light emitting direction and is covered with a reflective material to serve as a reflective surface that reflects visible light.

### CITATION LIST

### Patent Literature

Patent Literature 1: Japanese Unexamined Patent Application Publication No. 2021-19015

### SUMMARY OF THE INVENTION

It is desired that a light emitting device that uses a fine light emitting element as a light source as described above be improved in light extraction efficiency.

It is desirable to provide a light emitting device, a method of manufacturing light emitting device, and an image display apparatus that each make it possible to improve light extraction efficiency.

A light emitting device according to one embodiment of the present disclosure includes: a driving substrate; a compound semiconductor layer that has a first surface serving as a light exit surface and a second surface located on a side opposite to the first surface and opposed to the driving substrate, the compound semiconductor layer including a first electrical conductivity type layer, an active layer, and a second electrical conductivity type layer that are stacked in this order from a side of the driving substrate, and including a mesa section that includes the first electrical conductivity type layer, the active layer, and a portion of the second electrical conductivity type layer; a first transparent electrode layer formed on a side, of the first electrical conductivity type layer, that is closer to the driving substrate, and including an enlarged-width section that is larger in width than the mesa section; and a first light reflection film provided around the mesa section with a first insulating film interposed therebetween, the first light reflection film forming an inclined surface that is at an acute angle with respect to the first surface.

A method of manufacturing a light emitting device according to one embodiment of the present disclosure includes: forming a mesa section through etching a compound semiconductor layer from a side of a first electrical conductivity type layer, the compound semiconductor layer including the first electrical conductivity type layer, an active layer, and a second electrical conductivity type layer that are stacked in this order, the mesa section including the first electrical conductivity type layer, the active layer, and a portion of the second electrical conductivity type layer; embedding an insulating film in a first groove section formed around the mesa section through the etching; forming a second groove section having a tapered shape through etching the insulating film; and forming a first transparent electrode layer on the first electrical conductivity type layer in the mesa section after forming a first light reflection film on a side surface and a bottom surface of the second groove section, the first transparent electrode layer including an enlarged-width section that is larger in width than the mesa section.

An image display apparatus according to one embodiment of the present disclosure includes a light emitting device. The image display apparatus includes, as the light emitting device, the above-described light emitting device according to one embodiment of the present disclosure.

According to the light emitting device of one embodiment of the present disclosure, the method of manufacturing a light emitting device of one embodiment of the present disclosure, and the image display apparatus according to one embodiment of the present disclosure, the first transparent electrode layer including the enlarged-width section that is large in width than the mesa section is provided on a side, of the mesa section, that is closer to the first electrical conductivity type layer, the mesa section including the first electrical conductivity type layer, the active layer, and the portion of the second electrical conductivity type layer stacked in this order from the side of the driving substrate, and the first light reflection film that is provided around the mesa section with the first insulating film interposed therebetween, the first light reflection film forming an inclined surface that is at an acute angle with respect to the light exit surface. This makes it possible to independently control angles of a side surface of the mesa section and the inclined surface of the first light reflection film.

### BRIEF DESCRIPTION OF THE DRAWINGS

FIG. 1 is a schematic cross-sectional view illustrating an example of a configuration of a light emitting device according to an embodiment of the present disclosure.

FIG. 2 is a schematic diagram illustrating an example of a planar configuration of the whole light emitting device illustrated in FIG. 1.

FIG. 3 is a schematic diagram enlarging a portion of the planar configuration of the light emitting device illustrated in FIG. 2.

FIG. 4 is a schematic cross-sectional view of detailed configurations of a mesa section and its surroundings illustrated in FIG. 1.

FIG. 5 is a schematic plan view of an example of the mesa section and its surroundings illustrated in FIG. 4.

FIG. 6A is a schematic diagram illustrating another example of planar shapes of a light reflection film and the mesa section illustrated in FIG. 1.

FIG. 6B is a schematic diagram illustrating another example of planar shapes of the light reflection film and the mesa section illustrated in FIG. 1.

FIG. 6C is a schematic diagram illustrating another example of planar shapes of the light reflection film and the mesa section illustrated in FIG. 1.

FIG. 7A is a schematic cross-sectional view for describing an example of a manufacturing process of the light emitting device illustrated in FIG. 1.

FIG. 7B is a schematic cross-sectional view illustrating a subsequent process after FIG. 7A.

FIG. 7C is a schematic cross-sectional view illustrating a subsequent process after FIG. 7B.

FIG. 7D is a schematic cross-sectional view illustrating a subsequent process after FIG. 7C.

FIG. 7E is a schematic cross-sectional view illustrating a subsequent process after FIG. 7D.

FIG. 7F is a schematic cross-sectional view illustrating a subsequent process after FIG. 7E.

FIG. 7G is a schematic cross-sectional view illustrating a subsequent process after FIG. 7F.

FIG. 7H is a schematic cross-sectional view illustrating a subsequent process after FIG. 7G.

FIG. 7I FIG. 7I is a schematic cross-sectional view illustrating a subsequent process after FIG. 7H.

FIG. 7J is a schematic cross-sectional view illustrating a subsequent process after FIG. 7I.

FIG. 7K is a schematic cross-sectional view illustrating a subsequent process after FIG. 7J.

FIG. 8A is a schematic cross-sectional view for describing another example of a manufacturing process of the light emitting device illustrated in FIG. 1.

FIG. 8B is a schematic cross-sectional view illustrating a subsequent process after FIG. 8A.

FIG. 8C is a schematic cross-sectional view illustrating a subsequent process after FIG. 8B.

FIG. 8D is a schematic cross-sectional view illustrating a subsequent process after FIG. 8C.

FIG. 8E is a schematic cross-sectional view illustrating a subsequent process after FIG. 8D.

FIG. 8F is a schematic cross-sectional view illustrating a subsequent process after FIG. 8E

FIG. 8G is a schematic cross-sectional view illustrating a subsequent process after FIG. 8F.

FIG. 9 is a schematic cross-sectional view illustrating an example of a configuration of a light emitting device according to a modification of the present disclosure.

FIG. 10 is a perspective view illustrating an example of a configuration of an image display apparatus according to an application example of the present disclosure.

FIG. 11 is a schematic diagram illustrating an example of a wiring layout of the image display apparatus illustrated in FIG. 10.

FIG. 12 is a perspective view illustrating an example of a configuration of an image display apparatus according to an application example of the present disclosure.

FIG. 13 is a perspective view illustrating a configuration of a mounting substrate illustrated in FIG. 12.

FIG. 14 is a perspective view illustrating a configuration of a unit substrate illustrated in FIG. 13.

FIG. 15 is a diagram illustrating an example of the image display apparatus according to the application examples of the present disclosure.

### MODES FOR CARRYING OUT THE INVENTION

Next, with reference to drawings, details of embodiments of the present disclosure will be described. The following description is a specific example of the present disclosure, and the present disclosure is not limited to the following embodiments. In addition, the present disclosure is not limited to placements, dimensions, dimensional ratios, and the like of respective structural elements in each diagram. It is to be noted that the description will be given in the following order.
1. Embodiment (an example of a light emitting device having an enlarged-width section in an electrode layer on a side of a mesa section and having a light reflection film serving as a light reflection surface in a lateral direction of the mesa section with an insulating layer interposed therebetween)
1-1. Configuration of Light Emitting Device
1-2. Manufacturing Method of Light Emitting Device
1-3. Actions and Effects
2. Modification (another examples of light emitting device)
3. Application Example

### 1. Embodiment

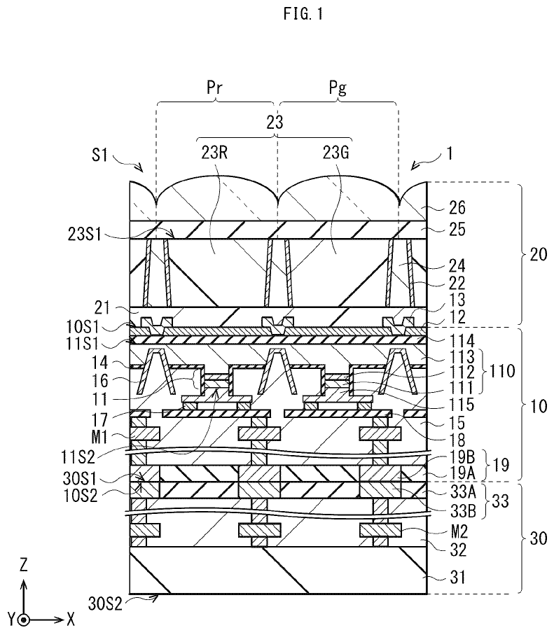

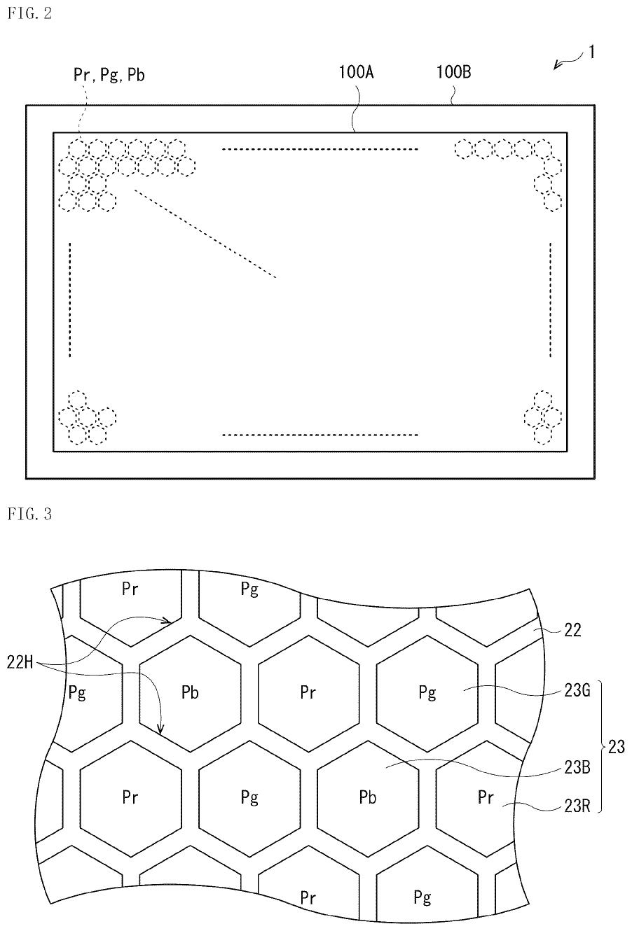

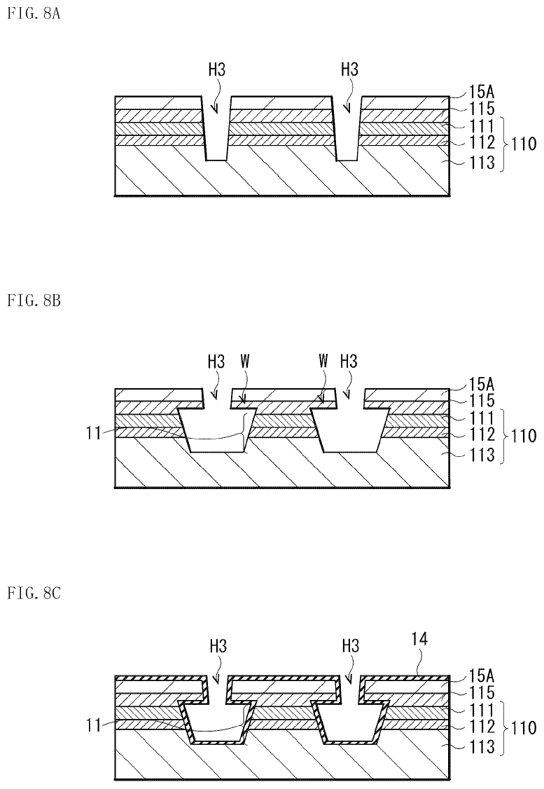

FIG. 1 schematically illustrates an example of a cross-sectional configuration of a light emitting device (light emitting device 1) according to an embodiment of the present disclosure. FIG. 2 schematically illustrates an example of a planar configuration of the whole light emitting device 1 illustrated in FIG. 1. The light emitting device 1 is suitably applicable to an image display apparatus (for example, an image display apparatus 100, see FIG. 10) that is what is called an LED display.

### 1-1. Configuration of Light Emitting Device

The light emitting device 1 includes a display region 100A and a frame region 100B, the display region 100A including a plurality of pixels (for example, red pixels Pr, green pixels Pg, and blue pixels Pb) that are two-dimensionally arrayed, the frame region 100B being disposed around the display region 100A. In the light emitting device 1, for example, an element substrate 10 and an wavelength conversion section 20 are stacked in this order in the display region 100A on a front surface (surface 30S1) side of a driving substrate 30 having the front surface (surface 30S1) and a back surface (surface 30S2) that are opposed to each other. The element substrate 10 includes respective light emitting sections for the plurality of pixels (for example, red pixels Pr, green pixels Pg, and blue pixels Pb).

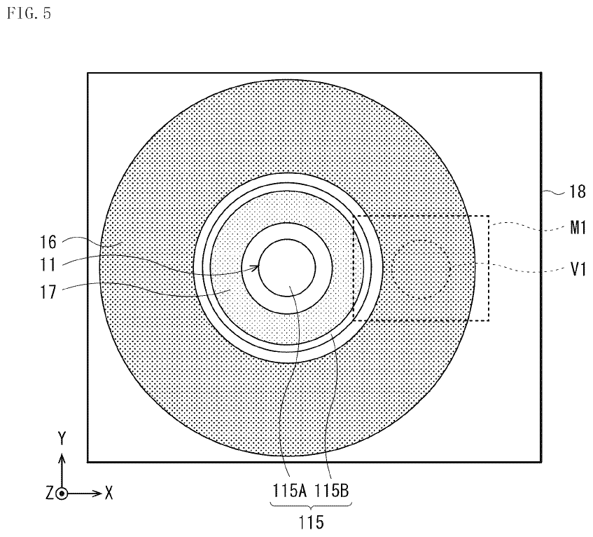

The light emitting device 1 includes a compound semiconductor layer 110 that has a surface 11S1 and a surface 11S2. The surface 11S1 serves as a light exit surface. The surface 11S2 is located on a side opposite to the surface 11S1 and is opposed to the driving substrate 30. The compound semiconductor layer 110 includes a mesa section 11 including a first electrical conductivity type layer 111, an active layer 112, and a portion of a second electrical conductivity type layer 113 as the light emitting section for each pixel (for example, red pixels Pr, green pixels Pg, and blue pixels Pb). According to the present embodiment, an electrode layer 115 including an enlarged-width section W that is larger in width than the mesa section 11 and a light reflection film 16 that forms a light reflection surface 16S at an acute angle with respect to the surface 11S1 around the mesa section 11 with an insulating layer 15 interposed therebetween are provided on a surface (the surface 11S2) of the first electrical conductivity type layer 111 closer to the driving substrate 30 (see FIG. 4).

The compound semiconductor layer 110 corresponds to a specific example of the “compound semiconductor layer” according to embodiments of the present disclosure. The surface 11S1 corresponds to the “first surface” according to the embodiments of the present disclosure. The surface 11S2 corresponds to the “second surface” according to the embodiments of the present disclosure. In addition, the mesa section 11 corresponds to a specific example of the “mesa section” according to the embodiments of the present disclosure. The electrode layer 115 corresponds to a specific example of the “first transparent electrode layer” according to the embodiments of the present disclosure. The light reflection film 16 corresponds to a specific example of the “first light reflection film” according to the embodiments of the present disclosure. The driving substrate 30 corresponds to a specific example of the “driving substrate” according to the embodiments of the present disclosure.

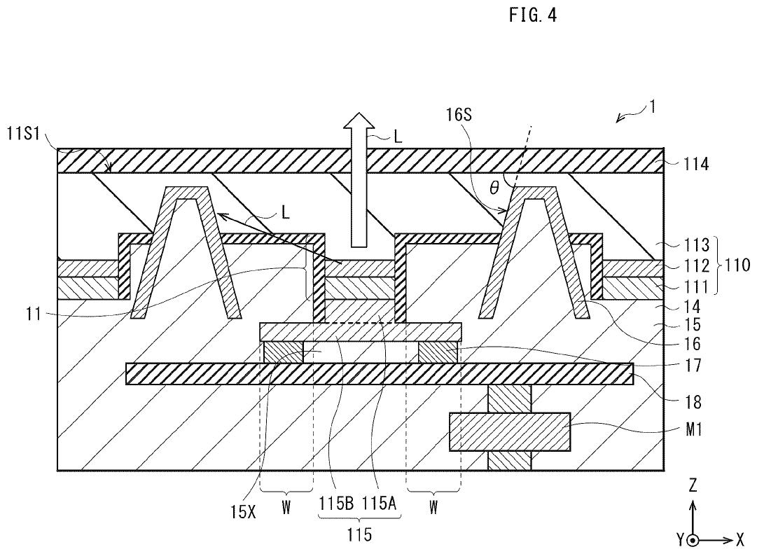

As described above, the element substrate 10 includes a plurality of pixels (for example, red pixels Pr, green pixels Pg, and blue pixels Pb) that are two-dimensionally arrayed in the display region 100A. Specifically, for example, as illustrated in FIG. 3, the plurality of pixels (for example, red pixels Pr, green pixels Pg, and blue pixels Pb) has a substantially regular hexagonal planar shape and is disposed in a honeycomb pattern. Each of the plurality of pixels (for example, red pixels Pr, green pixels Pg, and blue pixels Pb) includes the mesa section 11. On the surface 11S1 side of a plurality of the mesa sections 11, an electrode layer 114, an insulating layer 12, and an extraction electrode 13 are formed in this order.

Each of the plurality of mesa sections 11 is a solid-state light emitting element that emits light of a predetermined wavelength band from the surface 11S1, such as a light emitting diode (LED) chip. The LED chip represents a chip obtained by cutting a wafer whose crystal has grown, which is not in a package type surrounded by a molding resin or the like. The mesa section 11 is called a micro LED since it has a size of, for example, 1.0 μm or above and 5.0 μm or less.

The mesa section 11 includes the first electrical conductivity type layer 111, the active layer 112, and the second electrical conductivity type layer 113 that are stacked in this order, and the second electrical conductivity type layer has a top surface serving as the light exit surface (surface 11S1).

For example, the first electrical conductivity type layer 111 is formed by an n-type GaN-based semiconductor material. The active layer 112 has, for example, a multi-quantum-well structure in which InGaN and GaN are alternately stacked, and has a light emitting region therein. From the active layer 112, for example, light in a blue band of 430 nm or more and 500 nm or less is extracted. In addition, light having a wavelength corresponding to, for example, an ultraviolet region (ultraviolet light) may be extracted from the active layer 112. For example, the second electrical conductivity type layer 113 is formed by a p-type GaN-based semiconductor material.

The electrode layer 114 is formed on the second electrical conductivity type layer 113 as a common electrode for the plurality of mesa sections 11. The electrode layer 114 is in ohmic contact with the second electrical conductivity type layer 113. For example, the electrode layer 114 is formed by transparent electrode material such as indium tin oxide (ITO), indium zinc oxide (IZO), zinc oxide (ZnO), tin oxide (SnO), titanium oxide (TiO), graphene, or IGZO.

The insulating layer 12 is formed by silicon oxide (SiO), silicon nitride (SiN), or the like, for example.

The extraction electrode 13 applies voltage to the second electrical conductivity type layer 113. For example, the extraction electrode 13 is electrically coupled to the electrode layer 114 via an opening that is made in the insulating layer 12 between adjacent pixels. For example, in the display region 100A, the extraction electrodes 13 is successively formed between the plurality of pixels that are disposed in the honeycomb pattern, and extends to a portion of the frame region 100B. The extraction electrode 13 is formed by using a multilayer film (Ti/Al) of titanium (Ti) and aluminum (Al), a multilayer film (Cr/Au) of chromium (Cr) and gold (Au), or the like.

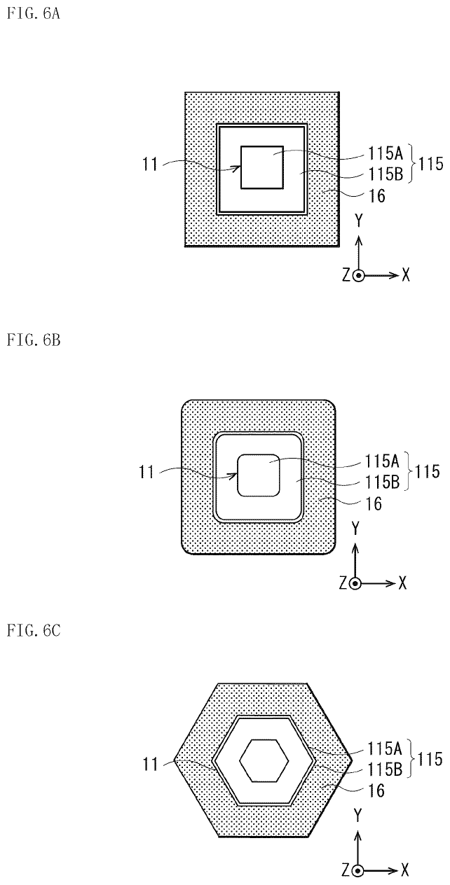

FIG. 4 schematically illustrates details of a cross-sectional configuration of the mesa section 11 and its surroundings illustrated in FIG. 1. FIG. 5 schematically illustrates an example of a planar configuration of the mesa section 11 and its surroundings illustrated in FIG. 4.

On the surface 11S2 side of the plurality of mesa sections 11, the electrode layers 115 are formed for the respective mesa sections 11. On the surface 11S2 side of the plurality of mesa sections 11, an insulating film 14 and the insulating layer 15 are also formed. In the insulating layer 15, the light reflection film 16 is formed to surround the mesa section 11 with the insulating layer 15 interposed therebetween. The insulating layer 15 further includes a contact electrode 17, a light reflection film 18, and a plurality of wirings including wiring M1.

The electrode layer 115 applies voltage to the first electrical conductivity type layer 111. For example, the electrode layer 115 includes a plurality of layers that are a first layer 115A and a second layer 115B, for example. The first layer 115A is provided on a lower surface (surface 11S2) of the mesa section 11, for example, has substantially a same planar shape as the mesa section 11, and forms substantially a same side surface as the mesa section 11. The second layer 115B forms the enlarged-width section W that is larger in width than the mesa section 11. The second layer 115B has a lower surface (surface on a side opposite to the mesa-section side) is parallel to the surface 11S1 of the mesa section 11. The electrode layer 115 including the first layer 115A and the second layer 115B is in ohmic contact with the first electrical conductivity type layer 111. For example, the electrode layer 115 is formed by transparent electrode material such as indium tin oxide (ITO), indium zinc oxide (IZO), zinc oxide (ZnO), tin oxide (SnO), titanium oxide (TiO), graphene, or IGZO.

The insulating film 14 is provided along the side surface of the mesa section 11 including the first layer 115A of the electrode layer 115, and along the second electrical conductivity type layer 113 exposed on the driving-substrate 30 side. The insulating film 14 is formed by silicon oxide (SiO), silicon nitride (SiN), or the like, for example.

The plurality of mesa sections 11 is embedded in the insulating layer 15 that forms a flat surface on a surface 10S2 side of the element substrate 10. The insulating layer 15 is formed by using, for example, silicon oxide (SiO), silicon nitride (SiN), silicon oxynitride (SiON), titanium oxide (TiO), aluminum oxide (AlO), tantalum oxide (TaO), silicon carbide (SiOC), SiOCN, or the like.

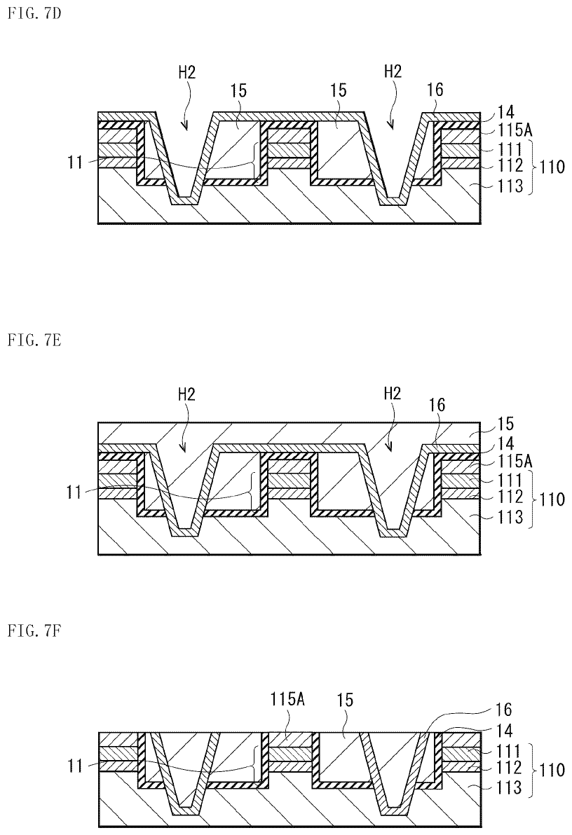

The light reflection film 16 blocks and reflects light (output light L) output from the active layer 112 in an oblique direction (for example, adjacent pixel direction) to improve an efficiency of extracting light from the light exit surface (surface 11S1). As described above, the light reflection film 16 is formed to surround the mesa section 11 with the insulating layer 15 interposed therebetween, for example. Specifically, for example, as illustrated in FIG. 7D, the light reflection film 16 is formed on a side surface of a groove H2 that penetrates the insulating layer 15 provided around the mesa section 11 and that reaches inside the second electrical conductivity type layer 113, to form a light reflection surface 16S at an acute angle (θ) with respect to the surface 11S1, for example. For example, the light reflection surface 16S preferably has an inclination angle of 45° to 75° that achieves high reflection effects. The groove H2 is filled with the insulating layer 15. The light reflection film 16 is formed by using metal material having light blocking effect and light reflectivity. Examples of the metal material used for forming the light reflection film 16 include metals having high reflectance in a visible light region. Specific examples of the material for the light reflection film 16 include aluminum (Al), silver (Ag), copper (Cu), gold (Au), platinum (Pt), rhodium (Rh), and alloys thereof such as ACX.

The contact electrode 17 electrically couples the electrode layer 115 to the light reflection film 18. According to the present embodiment, the contact electrode 17 is formed outside the mesa section 11 in such a manner that the electrode layer 115 and the light reflection film 18 are electrically coupled via the enlarged-width section W of the electrode layer 115. Specifically, as illustrated in FIG. 5, the contact electrode 17 is provided outside the mesa section 11 to surround the mesa section 11 for example, in plan view. Examples of material for forming the contact electrode 17 include copper (Cu), aluminum (Al), tungsten (W), silver (Ag), and alloys thereof. Specifically, it is possible to form the contact electrode 17 as a stacked film of titanium (Ti) alloy and tungsten (W), a stacked film of Ti alloy and Al alloy, or a stacked film of TI alloy, tantalum (Ta) alloy, and Cu alloy, for example.

The light reflection film 18 forms a cavity structure in the surface 11S2 of the mesa section 11 with the electrode layer 115, and reflects light (output light L) output from the active layer 112 in aback-surface direction (for example, driving-substrate 30 direction) to improve an efficiency of extracting light from the light exit surface (surface 11S1). The light reflection film 18 has a surface that is opposed to the mesa section 11 and that is parallel to the lower surface of the electrode layer 115 and the mesa section 11. In addition, the light reflection film 18 also serves as wiring for applying voltage to the first electrical conductivity type layer 111. The light reflection film 18 preferably extends to an outside of the light reflection surface 16S formed by at least the light reflection film 16 in plan view, in such a manner that light does not leak into the driving-substrate 30 side from a gap between the light reflection film 16 and the electrode 115B or the like included in the enlarged-width section W. Examples of the metal material used for forming the light reflection film 18 include metals having high reflectance in a visible light region. Specific examples of the material for the light reflection film 18 include aluminum (Al), silver (Ag), copper (Cu), gold (Au), platinum (Pt), rhodium (Rh), and alloys thereof such as ACX.

As a barrier film, an insulating layer 15X having light transparency is formed between the electrode layer 115 and the light reflection film 18. The insulating layer 15X corresponds to a specific example of a “second insulating film” according to the embodiments of the present disclosure. The insulating layer 15X is formed by using, for example, silicon oxide (SiO), silicon nitride (SiN), silicon oxynitride (SiON), titanium oxide (TiO), aluminum oxide (AlO), tantalum oxide (TaO), silicon carbide (SiOC), SiOCN, or the like. This makes it possible to suppress reactions between the electrode layer 115 and the light reflection film 18, and select a metal material having high optical reflectance as the material for the light reflection film 18.

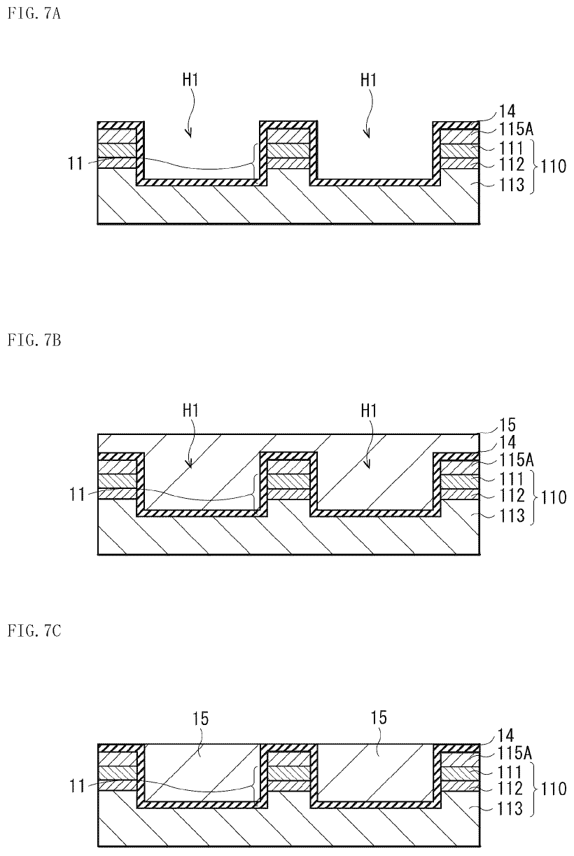

For example, the mesa section 11 has a planar shape that is similar to a planar shape of the light reflection film 16 formed around the mesa section 11. FIG. 6A to FIG. 6C illustrate other examples of the planar shapes of the mesa section 11 and the light reflection film 16 illustrated in FIG. 5. The planar shapes of the mesa section 11 and the light reflection film 16 formed around the mesa section 11 may be substantially elliptical shapes, aside from substantially circular shapes illustrated in FIG. 5. Alternatively, the planar shapes of the mesa section 11 and the light reflection film 16 formed around the mesa section 11 may be rectangular shape as illustrated in FIG. 6A, for example. Alternatively, the planar shapes of the mesa section 11 and the light reflection film 16 formed around the mesa section 11 may be rectangular shape with rounded corners as illustrated in FIG. 6B, for example. The planar shapes of the mesa section 11 and the light reflection film 16 formed around the mesa section 11 may be polygonal shapes such as hexagonal shapes as illustrated in FIG. 6C.

It is possible to form wirings (such as wiring M1) other than the light reflection film 18 that electrically couples the element substrate 10 to the driving substrate 30 and vias that electrically couple respective wirings, by using copper (Cu), aluminum (Al), tungsten (W), silver (Ag), or alloys thereof, for example. Alternatively, it is possible to form the wirings (such as wiring M1) other than the light reflection film 18 and the vias that electrically couple respective wirings, as a stacked film of titanium (Ti) alloy and tungsten (W), a stacked film of Ti alloy and Al alloy, or a stacked film of TI alloy, tantalum (Ta) alloy, and Cu alloy, for example.

It is to be noted that, as illustrated in FIG. 4 and FIG. 5, coupling between the light reflection film 18 and wiring (such as wiring M1) provided at a position closer to the driving substrate 30 than the light reflection film 18 is preferably made at a position outside the mesa section 11 in plan view in a way similar to the contact electrode 17. This allows a region of the light reflection film 18 that is opposed to the mesa section 11 to have a surface that is parallel to the lower surface of the electrode layer 115 and the mesa section 11.

In addition, the driving-substrate 30 side of the insulating layer 15 is provided with an insulating layer 19A including a plurality of pad sections 19B for bonding the element substrate 10 and the driving substrate 30 electrically and physically. The insulating layer 19A is formed by silicon oxide (SiO), silicon nitride (SiN), or the like, for example. The pad section 19B is formed by using copper (Cu), for example.

The wavelength conversion section 20 is provided on a light-extraction-surface S1 side of the element substrate 10. The wavelength conversion section 20 includes a planarizing layer 21, a partition wall layer 22, and a wavelength conversion layer 23. For example, the partition wall layer 22 has an opening 22H for each pixel, and the wavelength conversion layer 23 is formed inside the opening 22H. In addition, a light reflection film 24 is provided between the partition wall layer 22 and the wavelength conversion layer 23. In addition, a protection layer 25 is provided on the light-exit-surface S1 side of the wavelength conversion layer 23. In addition, an on-chip lens layer 26 is provided on the protection layer 25.

The planarizing layer 21 planarizes a surface of the element substrate 10 at the light-extraction-surface S1 side. The planarizing layer 21 is formed by silicon oxide (SiO), silicon nitride (SiN), or the like, for example.

The partition wall layer 22 suppresses color mixing due to leakage of light into adjacent RGB pixels (red pixels Pr, green pixels Pg, and blue pixels Pb) when applying the light emitting device 1 to the image display apparatus 100. For example, the partition wall layer 22 has a honeycomb structure. Specifically, as illustrated in FIG. 3, the partition wall layer 22 has the substantially regular hexagonal opening 22H for each of the plurality of pixels arranged in an array form, for example. For example, in cross-sectional view, the opening 22H has an inclined surface of less than 90° with respect to a surface 20S2 of the wavelength conversion section 20, the surface 20S2 being on a side opposite to a surface 20S1. That is, the partition wall layer 22 has a forward tapered shape among the adjacent color pixels Pr, Pg, and Pb in cross-sectional view. The partition wall layer 22 is preferably formed by using material having a high thermal conductivity and a high electric conductivity. For example, the partition wall layer 22 is formed by using metal material such as copper (Cu), aluminum (Al), gold (Au), nickel (Ni), or platinum (Pt).

The wavelength conversion layer 23 converts light output from the plurality of mesa sections 11 into desired wavelengths (for example, red (R)/green (G)/blue (B)) and outputs the converted light. The wavelength conversion layer 23 is formed in the opening 22H made above each mesa section 11. Specifically, the red pixel Pr is provided with a red wavelength conversion layer 23R that converts light outputted from the mesa section 11 into red band light (red light), the green pixel Pg is provided with a green wavelength conversion layer 23G that converts light outputted from the mesa section 11 into green band light (green light), and the blue pixel Pb is provided with a blue wavelength conversion layer 23B that converts light outputted from the mesa section 11 into blue band light (blue light).

It is possible to form the wavelength conversion layers 23R, 23G, and 23B by using respective quantum dots corresponding to the respective colors. Specifically, in a case of obtaining the red light, it is possible to select the quantum dots from among InP, GaInP, InAsP, CdSe, CdZnSe, CdTeSe, CdTe, and the like, for example. In a case of obtaining the green light, it is possible to select the quantum dots from among InP, GalInP, ZnSeTe, ZnTe, CdSe, CdZnSe, CdS, CdSeS, and the like, for example. In a case of obtaining the blue light, it is possible to select the quantum dots from among ZnSe, ZnTe, ZnSeTe, CdSe, CdZnSe, CdS, CdZnS, CdSeS, and the like. It is to be noted that, in a case where the mesa section 11 outputs the blue light as described above, the blue wavelength conversion layer 23B may be formed by a resin layer having light transparency.

The light reflection film 24 is provided on a side surface of the opening 22H for efficiency extracting, from the light extraction surface (surface 22S1) of the wavelength conversion layer 23, the respective color light beams that are output from the mesa sections 11 and converted by the respective wavelength conversion layers 23R, 23G, and 23B. The light reflection film 24 is formed by using metal material having light reflectivity. Examples of the metal material used for forming the light reflection film 24 include metals having high reflectance in a visible light region. Specific examples of the material include silver (Ag), aluminum (Al), copper (Cu), gold (Au), platinum (Pt), rhodium (Rh), and alloys thereof such as ACX.

It is to be noted that the light reflection film 24 does not necessarily have to be formed in a case where the partition wall layer 22 is formed by using the above-described metal material having the light reflectivity.

The protection layer 25 for protecting the surface of the light emitting device 1 is formed by silicon oxide (SiO), silicon nitride (SiN), or the like, for example.

The on-chip lens layer 26 is provided to cover the whole display region 100A and the whole frame region 100B. The on-chip lens layer 26 includes light transmissive material. For example, the on-chip lens layer 26 includes a monolayer film containing one selected from the group consisting of silicon oxide (SiOx), silicon nitride (SiNx), silicon oxynitride (SiCN), and the like, or alternatively, the on-chip lens layer 26 includes a stacked film containing at least two selected therefrom.

The driving substrate 30 is provided with a driving circuit or the like that controls driving of the plurality of pixels arranged in an array form in the display region 100A. For example, the driving substrate 30 includes a support substrate 31, an interlayer insulating layer 32, an insulating layer 33A, and a plurality of pad sections 33B. The support substrate 31 includes silicon (Si). The interlayer insulating layer 32 is provided on the support substrate 31 and includes a plurality of wirings (for example, wiring M2) and vias for electrically coupling wiring layers. The insulating layer 33A forms a joint surface to be joined to the element substrate 10. The plurality of pad sections 33B is embedded in the insulating layer 33A.

The interlayer insulating layer 32 is formed by using, for example, silicon oxide (SiO), silicon nitride (SiN), silicon oxynitride (SiON), titanium oxide (TiO), aluminum oxide (AlO), tantalum oxide (TaO), silicon carbide (SiOC), SiOCN, or the like.

The plurality of wirings (for example, wiring M2) and the vias for electrically coupling the respective wiring layers are formed by using copper (Cu), aluminum (Al), tungsten (W), silver (Ag), or alloys thereof, for example. The insulating layer 33A is formed by silicon oxide (SiO), silicon nitride (SiN), or the like, for example. The pad section 33B is formed by using copper (Cu), for example.

### 1-2. Manufacturing Method of Light Emitting Device

For example, it is possible to manufacture the light emitting device 1 according to the present embodiment as described below. FIG. 7A to FIG. 7K illustrate an example of manufacturing processes of the mesa section 11 and its surrounding components of the light emitting device 1.

First, the compound semiconductor layer 110 that includes the first electrical conductivity type layer 111, the active layer 112, and the second electrical conductivity type layer 113 stacked in this order is formed through epitaxial crystal growth using molecular-beam epitaxy (MBE), metalorganic chemical vapor deposition (MOCVD), or the like, for example. Next, the first layer 115A and an insulating layer (not illustrated) are formed on the compound semiconductor layer 110 through chemical vapor deposition (CVD), for example. Next, a surface of the insulating layer is planarized trough chemical mechanical polishing (CMP), for example.

Next, for example, as illustrated in FIG. 7A, a groove H1 whose bottom surface is located inside the second electrical conductivity type layer 113 is made from a side of the first electrical conductivity type layer 111 through photolithography and dry etching, to form the mesa section 11. Next, for example, an AlO film is formed over the top surface of the insulating layer and the side surface and the bottom surface of the groove H1 through atomic layer deposition (ALD) to form the insulating film 14. Next, as illustrated in FIG. 7B, the insulating layer 15 is formed on the insulating film 14 and the groove H1 is filled through the CVD, for example.

Next, as illustrated in FIG. 7C, the insulating film 14 is exposed and a surface of the insulating layer 15 is planarized through the CMP, for example. Next, for example, as illustrated in FIG. 7D, the tapered groove H2 whose bottom surface is located inside the second electrical conductivity type layer 113 is made in the insulating layer 15 embedded in the groove H1, through photolithography and wet etching. Next, as illustrated in FIG. 7D, the light reflection film 16 is formed on the insulating film 14, the insulating layer 15, the side surface and the bottom surface of the groove H2 through the CVD, for example.

Next, as illustrated in FIG. 7E, the insulating layer 15 is formed on the light reflection film 16 and the groove H2 is filled through the CVD, for example. Next, as illustrated in FIG. 7F, the first layer 115A is exposed and a surface of the insulating layer 15 is planarized through the CMP, for example. Next, as illustrated in FIG. 7G, the second layer 115B is formed over the exposed first layer 115A and the insulating layer 15, through the CVD, for example.

Next, as illustrated in FIG. 7H, the second layer 115B is patterned through the photolithography and etching, for example. This makes it possible to form the electrode layer 115 on the mesa section 11. The electrode layer 115 includes the enlarged-width section W that is larger in width than the mesa section 11. It is to be noted that the first layer 115A provided on the first electrical conductivity type layer 111 other than the mesa section 11 may be removed together with the second layer 115B at a time of patterning the second layer 115B.

Next, as illustrated in FIG. 7I, the insulating layer 15X serving as the barrier film is formed through the CVD, for example, to allow the electrode layer 115 to be embedded therein. Next, for example, as illustrated in FIG. 7J, an opening that penetrates the insulating layer 15X is made in an enlarged-width section X outside the mesa section 11 through the photolithography and etching, and then the contact electrode 17 is formed in the opening. Next, as illustrated in FIG. 7K, the light reflection film 18 is formed through the CVD, the photolithography, and the etching, for example. As described above, the mesa section 11 and its surrounding components of the light emitting device 1 are obtained.

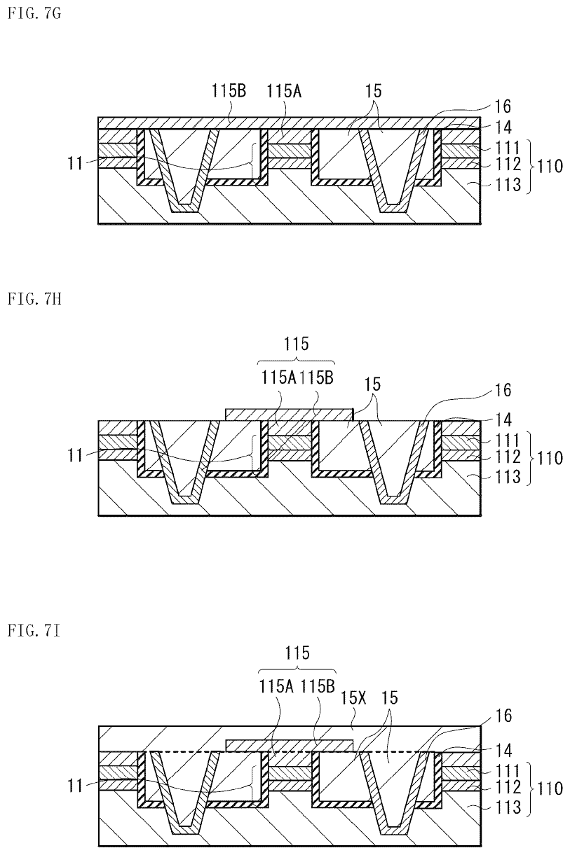

It is to be noted that the mesa section 11 may also be formed as follows. FIG. 8A to FIG. 8G illustrate another example of manufacturing processes of the mesa section 11 and its surrounding components of the light emitting device 1.

First, for example, as illustrated in FIG. 8A, a ring-like shaped groove H3 whose bottom surface is located inside the second electrical conductivity type layer 113 is made from the side of the first electrical conductivity type layer 111 through the photolithography and dry etching, for example. Next, as illustrated in FIG. 8B, isotropic etching of compound semiconductor only such as the wet etching is utilized and the compound semiconductor layer 110 in the groove H3 is etched toward a lateral direction to form the mesa section 11 and the electrode layer 115 that includes the enlarged-width section W that is larger in width than the mesa section 11.

Next, as illustrated in FIG. 8C, the insulating film 14 is formed on the insulating layer 15, the side surface and the bottom surface of the groove H3 through the ALD, for example. Next, as illustrated in FIG. 8D, an insulating layer 15B is formed on the insulating film 14 and the groove H3 is filled through the CVD, for example. Next, as illustrated in FIG. 8E, the insulating film 14 is exposed and a surface of the insulating layer 15B is planarized through the CMP, for example.

Next, for example, as illustrated in FIG. 8F, an opening that penetrates an insulating layer 15A is made at a position corresponding to the enlarged-width section W of the electrode layer 115 outside the mesa section 11 through the photolithography and etching, and then the contact electrode 17 is formed in the opening. Next, as illustrated in FIG. 8G, the light reflection film 18 is formed through the CVD, the photolithography, and the etching, for example. The mesa section 11 and its surrounding components of the light emitting device 1 are obtained in such a way.

### 1-3. Actions and Effects

In the light emitting device 1 according to the present embodiment, the electrode layer 115 including the enlarged-width section W that is larger in width than the mesa section 11 is provided on the lower surface (on the first electrical conductivity type layer 111) of the mesa section 11 including the first electrical conductivity type layer 111, the active layer 112, and the portion of the second electrical conductivity type layer 113 stacked in this order from the driving-substrate 30 side, and the light reflection film 16 forming the inclined surface (light reflection surface 16S) that is at an acute angle with respect to the light exit surface (surface 11S1) is provided around the mesa section 11 with the insulating layer 15 interposed therebetween. This allows independent control of angles of the side surface of the mesa section 11 and the inclined surface of the light reflection film 16. A description thereof will be provided below.

For example, it is desired to achieve further miniaturization of what is called a micro display that includes a micro LED as a light source. However, to achieve the miniaturization of the micro display, it is necessary to form a reflection film to improve light extraction efficiency. However, it is difficult to control an angle of a light-emitting-element side surface on which the reflection film is formed according to general processing technologies, and this makes it difficult to improve the light extraction efficiency.

In contrast, according to the present embodiment, the mesa section 11 including the first electrical conductivity type layer 111, the active layer 112, and the portion of the second electrical conductivity type layer 113 is formed, and the light reflection film 16 forming the light reflection surface 16S is formed around the mesa section 11 with the insulating layer 15 interposed therebetween. The insulating layer 15 is provided to embed the mesa section 11 therein. This makes it possible to independently control angles of the light reflection surface 16S by the light reflection film 16, separately from processing performed on the light-emitting-element side surface. For example, this makes it possible to form the light reflection surface 16S around the mesa section 11 at inclination angles of 45° to 75° that achieves high reflection effects.

Thus, the light emitting device 1 according to the present embodiment makes it possible to improve the light extraction efficiency. It is therefore possible to achieve a finer and higher-resolution image display apparatus.

In addition, general micro displays have problems that electrodes coupled to micro-LEDs have large areas and low reflectance, and malfunction occurs due to leakage of light output from the micro-LEDs into a driving-substrate side.

On the contrary, when using the light emitting device 1 according to the present embodiment, the electrode layer 115 including the enlarged-width section W that is larger in width than the mesa section 11 is provided on the lower surface (on the first electrical conductivity type layer 111) of the mesa section 11, and there is formed the light reflection film 18 under the electrode layer 115. This makes it possible to easily form the cavity structure in the lower surface of the mesa section 11, and reflect light (output light L) output from the active layer 112 in the back-surface direction (for example, driving-substrate 30 direction) to extract the reflected light from the light exit surface (surface 11S1). This makes it possible to further improve the light extraction efficiency.

Specifically, the electrode layer 115 according to the present embodiment has a stacked structure that includes the first layer 115A and the second layer 115B. The first layer 115A has substantially a same planar shape as the mesa section 11. The second layer 115B forms the enlarged-width section W. This makes it possible to easily control the film thickness of the electrode layer 115 that forms the cavity structure. Accordingly, it is possible to improve cavity performance of the electrode layer 115 and further improve light extraction efficiency.

In addition, as the barrier film, the insulating layer 15X is formed between the electrode layer 115 and the light reflection film 18 of the light emitting device 1 according to the present embodiment. This makes it possible to suppress reactions between the electrode layer 115 and the light reflection film 18, and select a metal material having high optical reflectance as the material for the light reflection film 18. Therefore, it becomes possible to satisfy both of wiring performance and light reflection performance of the light reflection film 18.

In addition, in the light emitting device 1 according to the present embodiment, the contact electrode 17 is formed at the enlarged-width section W of the electrode layer 115 outside the mesa section 11 to electrically couple the electrode layer 115 and the light reflection film 18. This makes it possible to prevent reduction in reflectance due to the contact electrode 17.

Next, a first modification and application examples of the present disclosure will be described. It is to be noted that structural elements corresponding to the above-described structural elements of the light emitting device 1 according to the above-described embodiment will be denoted with the same reference signs as the above-described embodiment, and repeated description will be omitted.

### 2. Modifications

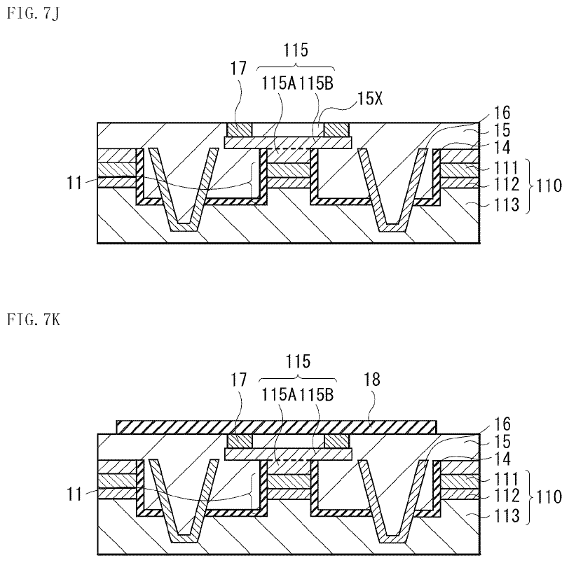

FIG. 9 is a schematic cross-sectional view illustrating an example of a configuration of the mesa section 11 and its surrounding components in a light emitting device (light emitting device 1A) according to a modification of the present disclosure. In a way similar to the light emitting device 1 according to the above-described embodiment, the light emitting device 1A is suitably applicable to an image display apparatus (for example, the image display apparatus 100, see FIG. 10) that is what is called an LED display.

As illustrated in FIG. 9, a light shielding section 41 may be substantially vertically formed on the light reflection film 18 toward the light exit surface (surface 11S1). Specifically, for example, the light shielding section 41 having a ring-like shape in the groove H2 provided with the light reflection film 16 is formed outside the light reflection surface 16S formed by the light reflection film 16 in such a manner that the light shielding section 41 surrounds the mesa section 11. The light shielding section 41 corresponds to a specific example of a “light shielding section” according to the modifications of the present disclosure. For example, a wiring 42 may be coupled to the light shielding section 41, and a fixed electric potential (for example, GND) may be applied thereto.

As described above, the light emitting device 1A according to the present modification includes the light shielding section 41 formed on the light reflection film 18 outside the light reflection film 16 in such a manner that the light shielding section 41 surrounds the mesa section 11. This makes it possible to reduce leakage of light into the driving-substrate 30 side from a gap between the electrode layer 115 and the light reflection film 16. Accordingly, in addition to the effects achieved according to the above-described embodiments, it becomes possible to further reduce leakage of light into the driving-substrate 30 side and prevent malfunction.

### 3. Application Example

### First Application Example

FIG. 10 is a perspective view illustrating an example of a schematic configuration of an image display apparatus (the image display apparatus 100). The image display apparatus 100 is what is called an LED display, and the light emitting device according to the present disclosure (for example, the light emitting device 1) is used as display pixels. As illustrated in FIG. 10, for example, the image display apparatus 100 includes a display panel 120 and a control circuit 140 that drives the display panel 120.

The display panel 120 includes a mounting substrate 120A and a counter substrate 120B that are superimposed on each other. The counter substrate 120B has a surface serving as a picture display surface, and the surface has the display region 100A in its central part and the frame region 100B serving as a non-display region around the display region 100A.

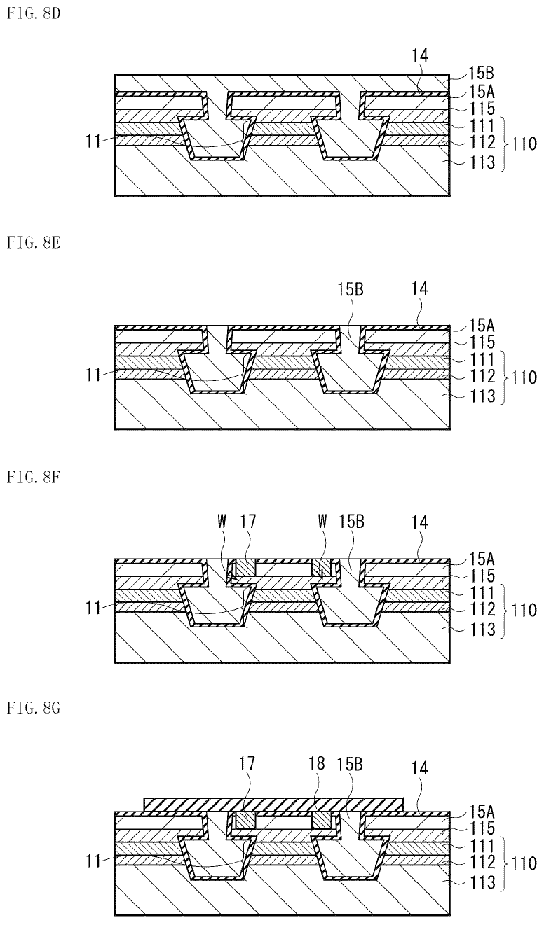

FIG. 11 is a diagram illustrating an example of wiring layout of a region corresponding to the display region 100A on a counter-substrate-120B-side surface of the mounting substrate 120A. As illustrated in FIG. 11, for example, a plurality of data wirings 124 is formed to extend in a predetermined direction and is arranged in parallel at a predetermined pitch in the region corresponding to the display region 100A on the surface of the mounting substrate 120A. The region corresponding to the display region 100A on the surface of the mounting substrate 120A further includes a plurality of scan wirings 125 that extend in a direction intersecting (for example, orthogonal to) the data wirings 124, and the plurality of scan wirings 125 is arranged in parallel at a predetermined pitch, for example. The data wirings 124 and the scan wirings 125 include, for example, conductive material such as Cu.

For example, the scan wiring 125 is formed on an uppermost layer, and is formed on an insulating layer (not illustrated) formed on a surface of a base material, for example. It is to be noted that the base material of the mounting substrate 120A includes, for example, a silicon substrate, a resin substrate, or the like. The insulating layer on the base material includes, for example, SiN, SiO, aluminum oxide (AlO), or resin material. On the other hand, the data wiring 124 is formed in a layer (for example, layer below the uppermost layer) different from the upper layer including the scan wiring 125. The data wiring 124 is formed in, for example, the insulating layer on the base material.

A display pixel 126 is adjacent to intersections of the data wiring 124 and the scan wiring 125. A plurality of the display pixels 126 is arranged in a matrix in the display region 100A. For example, the color pixels Pr, Pg, and Pb of the light emitting device 1 is implemented as the respective display pixels 126.

For example, the light emitting device 1 is provided with a pair of terminal electrodes for the respective color pixel Pr, Pg, and Pb, or is provided with a common terminal electrode and terminal electrodes for the respective color pixel Pr, Pg, and Pb. One of the terminal electrodes is electrically coupled to the data wiring 124, and another terminal electrode is electrically coupled to the scan wiring 125. For example, the one of the terminal electrodes is electrically coupled to a pad electrode 124B at an end of a branch 124A of the data wiring 124. In addition, for example, the other of the terminal electrodes is electrically coupled to a pad electrode 125B at an end of a branch 125A of the scan wiring 125.

For example, the pad electrodes 124B and 125B are formed on the uppermost layer and is provided at respective parts where the light emitting device 1 is mounted as illustrated in FIG. 11. Here, the pad electrodes 124B and 125B includes electrically conductive material such as Au (gold), for example.

The mounting substrate 120A is further provided with, for example, a plurality of support columns (not illustrated) for regulating an interval between the mounting substrate 120A and the counter substrate 120B. The support column may be provided in a region opposed to the display region 100A or may be provided in a region opposed to the frame region 100B.

The counter substrate 120B includes, for example, a glass substrate, a resin substrate, or the like. The counter substrate 120B may have a flat surface on the light emitting device 1 side, but preferably has a rough surface. The rough surface may be provided over a whole region opposed to the display region 100A, or may be provided in a region opposed to the display pixels 126 only. The rough surface has fine irregularities into which light emitted from the color pixels Pr, Pg, and Pb enters. It is possible to make the irregularities on the rough surface through sand blasting, dry etching, or the like, for example.

The control circuit 140 drives the respective display pixel 126 (respective light emitting device 1) on the basis of a picture signal. The control circuit 140 includes, for example, a data driver that drives the data wirings 124 coupled to the display pixels 126 and a scan driver that drives the scan wirings 125 coupled to the display pixels 126. For example, as illustrated in FIG. 10, the control circuit 140 may be provided separately from the display panel 120 and may be coupled to the mounting substrate 120A via the wirings, or may be mounted on the mounting substrate 120A.

### Second Application Example

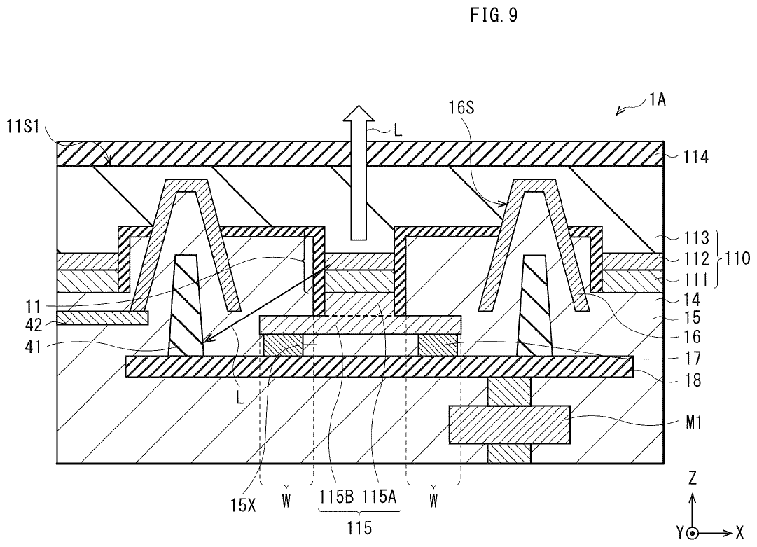

FIG. 12 is a perspective view illustrating another configuration example of an image display apparatus (an image display apparatus 200) that uses the light emitting device according to the present disclosure (for example, the light emitting device 1). The image display apparatus 200 is what is called a tiling display that uses a plurality of the light emitting devices including LEDs as light sources. For example, as illustrated in FIG. 12, the image display apparatus 200 includes a display panel 220 and a control circuit 240 that drives the display panel 220.

The display panel 220 is a display panel in which a mounting substrate 220A and a counter substrate 220B are superimposed on each other. The counter substrate 220B has a surface serving as a picture display surface, and the surface has a display section in its central part and a frame section serving as a non-display region around the display section (both sections are not illustrated). For example, the counter substrate 220B is disposed at a position opposed to the mounting substrate 220A with a predetermined gap therebetween. It is to be noted that the counter substrate 220B may be in contact with an upper surface of the mounting substrate 220A.

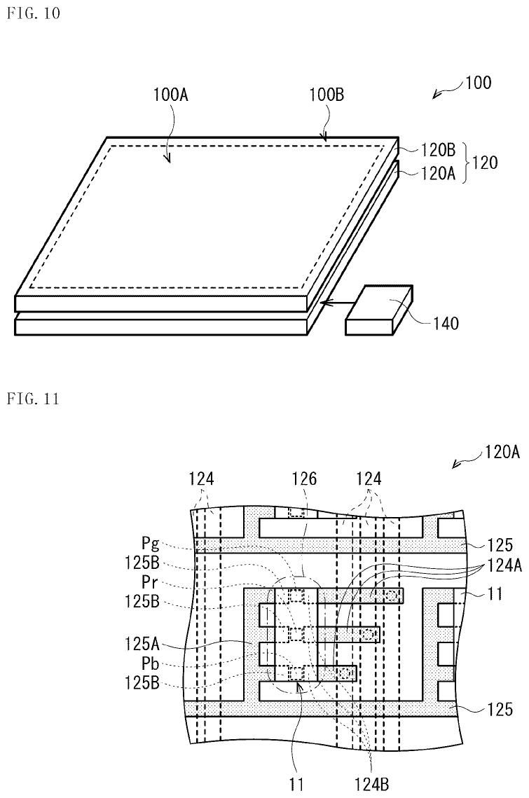

FIG. 13 schematically illustrates an example of a configuration of the mounting substrate 220A. For example, as illustrated in FIG. 13, the mounting substrate 220A includes a plurality of unit substrates 250 laid in a tile shape. Although FIG. 13 illustrates the example in which the mounting substrate 220A includes the nine unit substrates 250, the number of unit substrates 250 may be 10 or more or 8 or less.

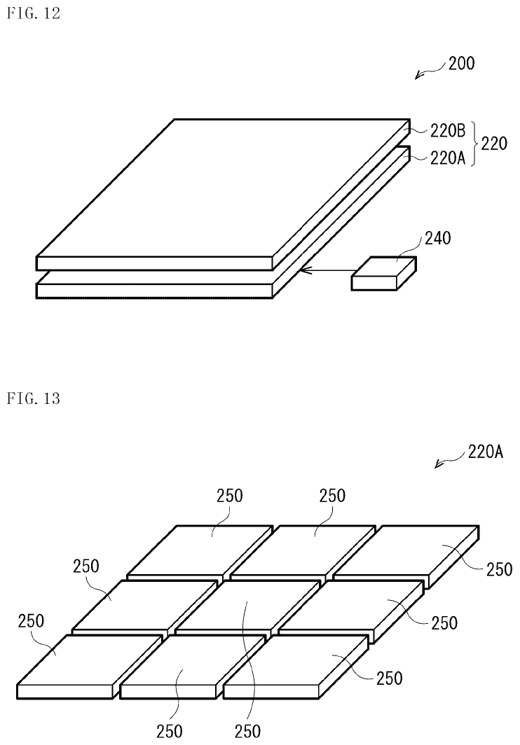

FIG. 14 illustrates an example of a configuration of the unit substrate 250. For example, the unit substrate 250 includes a plurality of light emitting devices 1 laid like tiles and a support substrate 260 that supports the light emitting devices 1. The unit substrate 250 further includes a control substrate (not illustrated). The support substrate 260 is implemented by a metal frame (metal plate), a wiring substrate, or the like, for example. In a case where the support substrate 260 is implemented by the wiring substrate, the support substrate 260 may also serve as the control substrate. In this case, at least one of the support substrate 260 or the control substrate is electrically coupled to the respective light emitting devices 1.

### Third Application Example

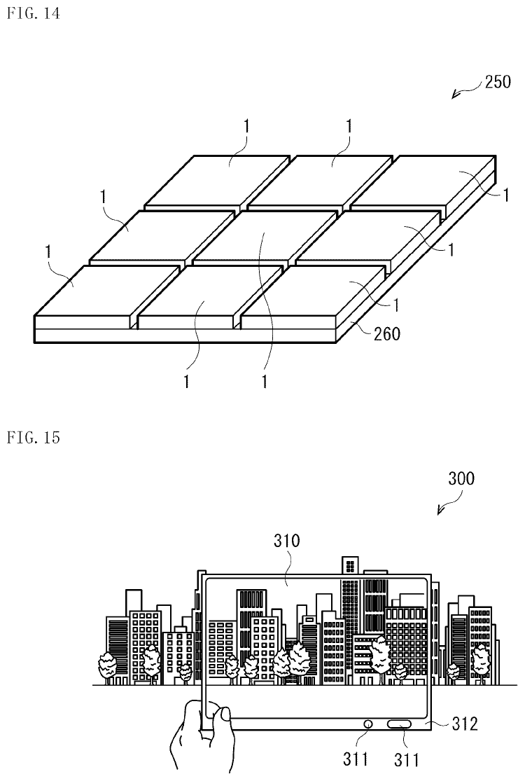

FIG. 15 illustrates an appearance of a transparent display 300. The transparent display 300 includes, for example, a display section 310, an operation section 311, and a housing 312. The display section 310 uses the light emitting device (for example, light emitting device 1) according to the present disclosure. The transparent display 300 makes it possible to display images, text information, and the like while letting a background of the display section 310 to pass through.

The transparent display 300 includes a mounting substrate that has light transparency. The light emitting device 1 is provided with electrodes, each of which is formed by using electrically conductive material having light transparency like the mounting substrate. Alternatively, the electrodes have a structure that is difficult to be visually recognized by supplementing their wiring width or by thinning the thickness of the wiring. Further, it is possible to display black on the transparent display 300 by superimposing liquid crystal layers provided with a driving circuit, for example. This makes it possible to switch between a transparent mode and a black display mode by controlling a light distribution direction of liquid crystals.

The present technology has been described above with reference to the embodiments, modifications, and application examples. However, the present technology is not limited thereto, and various kinds of modifications thereof can be made. For example, the example in which light output from the mesa section 11 is blue light or ultraviolet light has been described in the above-described embodiment or the like. However, the present technology is not limited thereto. For example, the light emitting device 1 may use a light emitting element that outputs two or more types of light such as a set of blue light and green light or a set of ultraviolet light and green light.

In addition, the example in which the second electrical conductivity type layer 113 is continuous between adjacent pixels has been described in the above-described embodiment or the like. However, the present technology is not limited thereto. For example, like the first electrical conductivity type layer 111 and the active layer 112, the second electrical conductivity type layer 113 may be prepared for each pixel and they may be discontinuous.

Further, in the above-described embodiments and the like, the respective members included in the light emitting device 1 and the like have been specifically described, but it is not necessary to include all the members, and other members may be further provided.

It is to be noted that the effects described herein are only for illustrative purposes and there may be other effects.

The present technology may be configured as follows. According to the present technology having the following configurations, it is possible to independently control angles of the inclined surface of the first light reflection film and the side surface of the mesa section. This makes it possible to improve the light extraction efficiency.
(1)

A light emitting device including:
a driving substrate;
a compound semiconductor layer that has a first surface serving as a light exit surface and a second surface located on a side opposite to the first surface and opposed to the driving substrate, the compound semiconductor layer including a first electrical conductivity type layer, an active layer, and a second electrical conductivity type layer that are stacked in this order from a side of the driving substrate, and including a mesa section that includes the first electrical conductivity type layer, the active layer, and a portion of the second electrical conductivity type layer;
a first transparent electrode layer formed on a side, of the first electrical conductivity type layer, that is closer to the driving substrate, and including an enlarged-width section that is larger in width than the mesa section; and
a first light reflection film provided around the mesa section with a first insulating film interposed therebetween, the first light reflection film forming an inclined surface that is at an acute angle with respect to the first surface.
(2)

The light emitting device according to (1), in which the first transparent electrode layer includes a first layer and a second layer, the first layer being in contact with the second surface and having substantially a same planar shape as the mesa section, the second layer forming the enlarged-width section.
(3)

The light emitting device according to (1) or (2), further including a second light reflection film provided substantially parallel to the second surface, with the first transparent electrode layer interposed therebetween.
(4)

The light emitting device according to (3), further including a second insulating film between the first transparent electrode layer and the second light reflection film, the second insulating film having light transparency.
(5)

The light emitting device according to (3) or (4), in which the first transparent electrode layer and the second light reflection film are electrically coupled to each other via a contact electrode provided in the enlarged-width section.
(6)

The light emitting device according to (5), in which the second light reflection film includes an electrically-conductive film having light reflectivity, and also serves as a wiring layer to apply a voltage to the first electrical conductivity type layer via the contact electrode and the first transparent electrode layer.
(7)

The light emitting device according to any one of (3) to (6), in which
the second light reflection film extends to an outside of the first light reflection film in plan view, and
the light emitting device further includes a light shielding section provided upright toward the light exit surface, the light shielding section being located outside the first light reflection film, on a surface of the second light reflection film opposed to the first transparent electrode layer.
(8)

The light emitting device according to any one of (1) to (7), in which the compound semiconductor layer includes a plurality of the mesa sections.
(9)

The light emitting device according to (7) or (8), in which a portion of the first light reflection film is embedded in the second electrical conductivity type layer continuous with the mesa section adjacent thereto.
(10)

The light emitting device according to any one of (1) to (9), in which a planar shape of the first transparent electrode layer is similar to a planar shape of the mesa section.
(11)

The light emitting device according to any one of (1) to (10), in which a planar shape of the first transparent electrode layer is substantially circular, substantially rectangular, substantially elliptical, or substantially polygonal.
(12)

The light emitting device according to any one of (8) to (11), further including a second transparent electrode layer that is provided on a side of the second electrical conductivity type layer closer to the first surface, and that is common to the plurality of mesa sections.
(13)

A method of manufacturing a light emitting device, the method including:
forming a mesa section through etching a compound semiconductor layer from a side of a first electrical conductivity type layer, the compound semiconductor layer including the first electrical conductivity type layer, an active layer, and a second electrical conductivity type layer that are stacked in this order, the mesa section including the first electrical conductivity type layer, the active layer, and a portion of the second electrical conductivity type layer;
embedding an insulating film in a first groove section formed around the mesa section through the etching;
forming a second groove section having a tapered shape through etching the insulating film; and
forming a first transparent electrode layer on the first electrical conductivity type layer in the mesa section after forming a first light reflection film on a side surface and a bottom surface of the second groove section, the first transparent electrode layer including an enlarged-width section that is larger in width than the mesa section.
(14)

The method of manufacturing the light emitting device according to (13), further including forming a second insulating film after the forming of the first transparent electrode layer, the second insulating film allowing the first transparent electrode layer to be embedded therein.
(15)

The method of manufacturing the light emitting device according to (14), further including:
after the forming of the second insulating film, forming, on the enlarged-width section, an opening that penetrates the second insulating film in plan view, and thereafter forming a contact electrode inside the opening, and
forming a second light reflection film on the second insulating film, the second light reflection film extending to an outside of the first light reflection film in plan view.
(16)

An image display apparatus including
a light emitting device,
the light emitting device including:
a driving substrate;
a compound semiconductor layer that has a first surface serving as a light exit surface and a second surface located on a side opposite to the first surface and opposed to the driving substrate, the compound semiconductor layer including a first electrical conductivity type layer, an active layer, and a second electrical conductivity type layer that are stacked in this order from a side of the driving substrate, and including a mesa section that includes the first electrical conductivity type layer, the active layer, and a portion of the second electrical conductivity type layer;
a first transparent electrode layer formed on a side, of the first electrical conductivity type layer, that is closer to the driving substrate, and including an enlarged-width section that is larger in width than the mesa section; and
a first light reflection film provided around the mesa section with a first insulating film interposed therebetween, the first light reflection film forming an inclined surface that is at an acute angle with respect to the first surface.

The present application claims the benefit of Japanese Priority Patent Application JP2023-048659 filed with the Japan Patent Office on Mar. 24, 2023, the entire contents of which are incorporated herein by reference.

It should be understood by those skilled in the art that various modifications, combinations, sub-combinations and alternations may occur depending on design requirements and other factors insofar as they are within the scope of the appended claims or the equivalents thereof.

What is claimed is:

1. A light emitting device, comprising:
a driving substrate;
a compound semiconductor layer that has a first surface serving as a light exit surface and a second surface located on a side opposite to the first surface and opposed to the driving substrate, the compound semiconductor layer including a first electrical conductivity type layer, an active layer, and a second electrical conductivity type layer that are stacked in this order from a side of the driving substrate, and including a mesa section that includes the first electrical conductivity type layer, the active layer, and a portion of the second electrical conductivity type layer;
a first transparent electrode layer formed on a side, of the first electrical conductivity type layer, that is closer to the driving substrate, and including an enlarged-width section that is larger in width than the mesa section; and
a first light reflection film provided around the mesa section with a first insulating film interposed therebetween, the first light reflection film forming an inclined surface that is at an acute angle with respect to the first surface.

2. The light emitting device according to claim 1, wherein the first transparent electrode layer includes a first layer and a second layer, the first layer being in contact with the second surface and having substantially a same planar shape as the mesa section, the second layer forming the enlarged-width section.

3. The light emitting device according to claim 1, further comprising
a second light reflection film provided substantially parallel to the second surface, with the first transparent electrode layer interposed therebetween.

4. The light emitting device according to claim 3, further comprising
a second insulating film between the first transparent electrode layer and the second light reflection film, the second insulating film having light transparency.

5. The light emitting device according to claim 3, wherein the first transparent electrode layer and the second light reflection film are electrically coupled to each other via a contact electrode provided in the enlarged-width section.

6. The light emitting device according to claim 5, wherein the second light reflection film includes an electrically-conductive film having light reflectivity, and also serves as a wiring layer to apply a voltage to the first electrical conductivity type layer via the contact electrode and the first transparent electrode layer.

7. The light emitting device according to claim 3, wherein
the second light reflection film extends to an outside of the first light reflection film in plan view, and
the light emitting device further comprises a light shielding section provided upright toward the light exit surface, the light shielding section being located outside the first light reflection film, on a surface of the second light reflection film opposed to the first transparent electrode layer.

8. The light emitting device according to claim 1, wherein the compound semiconductor layer includes a plurality of the mesa sections.

9. The light emitting device according to claim 7, wherein a portion of the first light reflection film is embedded in the second electrical conductivity type layer continuous with the mesa section adjacent thereto.

10. The light emitting device according to claim 1, wherein a planar shape of the first transparent electrode layer is similar to a planar shape of the mesa section.

11. The light emitting device according to claim 1, wherein a planar shape of the first transparent electrode layer is substantially circular, substantially rectangular, substantially elliptical, or substantially polygonal.

12. The light emitting device according to claim 8, further comprising
a second transparent electrode layer that is provided on a side of the second electrical conductivity type layer closer to the first surface, and that is common to the plurality of mesa sections.

13. A method of manufacturing a light emitting device, the method comprising:
forming a mesa section through etching a compound semiconductor layer from a side of a first electrical conductivity type layer, the compound semiconductor layer including the first electrical conductivity type layer, an active layer, and a second electrical conductivity type layer that are stacked in this order, the mesa section including the first electrical conductivity type layer, the active layer, and a portion of the second electrical conductivity type layer;
embedding an insulating film in a first groove section formed around the mesa section through the etching;
forming a second groove section having a tapered shape through etching the insulating film; and
forming a first transparent electrode layer on the first electrical conductivity type layer in the mesa section after forming a first light reflection film on a side surface and a bottom surface of the second groove section, the first transparent electrode layer including an enlarged-width section that is larger in width than the mesa section.

14. The method of manufacturing the light emitting device according to claim 13, further comprising forming a second insulating film after the forming of the first transparent electrode layer, the second insulating film allowing the first transparent electrode layer to be embedded therein.

15. The method of manufacturing the light emitting device according to claim 14, further comprising:
after the forming of the second insulating film, forming, on the enlarged-width section, an opening that penetrates the second insulating film in plan view, and thereafter forming a contact electrode inside the opening, and
forming a second light reflection film on the second insulating film, the second light reflection film extending to an outside of the first light reflection film in plan view.

16. An image display apparatus, comprising
a light emitting device,
the light emitting device including:
a driving substrate;
a compound semiconductor layer that has a first surface serving as a light exit surface and a second surface located on a side opposite to the first surface and opposed to the driving substrate, the compound semiconductor layer including a first electrical conductivity type layer, an active layer, and a second electrical conductivity type layer that are stacked in this order from a side of the driving substrate, and including a mesa section that includes the first electrical conductivity type layer, the active layer, and a portion of the second electrical conductivity type layer;
a first transparent electrode layer formed on a side, of the first electrical conductivity type layer, that is closer to the driving substrate, and including an enlarged-width section that is larger in width than the mesa section; and
a first light reflection film provided around the mesa section with a first insulating film interposed therebetween, the first light reflection film forming an inclined surface that is at an acute angle with respect to the first surface.
